(19) United States
(12) Patent Application Publication
(10) Pub. No.: US 2001/0026150 A1
(43) Pub. Date: Oct. 4, 2001

(54) Method and apparatus for measuring bit rates in digital communication systems

(76) Inventor: Gunther Klenner, Wittelsbacherstr (DE)

Correspondence Address: EPSTEIN, EDELL & RETZER, Suite 400, 1901 Research Boulevard, Rockville, MD, 20850-3164, US

(21) Appl. No.: 09/822,217

(22) Filed: Apr. 2, 2001

(30) Foreign Application Priority Data
Apr. 1, 2000 (DE) 100 16 469.2-31

(51) Int. Cl. G01R 13/20

(52) U.S. Cl. 324/76.26

(57) ABSTRACT

In a method for measuring the receiver sensitivity of communication devices provided for operation in a digital communication net, wherein the fulfillment of a first criterion is tested at a pre-determined data transmission rate and at a pre-determined reception level, a substantial increase of the testing speed is realized by conducting the testing at a higher data transmission rate than the pre-determined data transmission rate at the pre-determined reception level, wherein the fulfillment of a second criterion is tested, and wherein the second criterion is determined from the first criterion. Further, in a method for measuring the bit error rate of communication devices provided for operation in a digital communication net, wherein at a pre-determined data transmission rate and at a pre-determined reception level a first bit error rate has to be obtained, a substantial increase of the speed of the measurement process is achieved by conducting the measurement at a higher data rate than the pre-determined data rate at the pre-determined reception level, wherein at the higher data transmission rate a second bit error rate is detected and wherein the first bit error rate is determined from the second bit error rate. Finally, the present invention relates to a testing device for carrying out the methods.

### BACKGROUND OF THE INVENTION

The present invention relates to a method for measuring or testing the receiver sensitivity of communication terminals or devices provided for operation in a digital communication net. Further, the present invention relates to a method of measuring the bit error rates of communication terminals provided for operation in a digital communication net. Still further, the present invention relates to a testing device for communication terminals provided for operation in a digital communication net, in particular for conducting the method according to the present invention.

### DESCRIPTION OF THE PRIOR ART

In the prior art testing devices for mobile or cellular telephones or base stations are known. As for a written disclosure therefor attention is drawn to the publication “Meβtechnik für GSM-Funktelefone” by R. Schoblick in Funkschau 16/97, pages 64 to 66. Such measurement apparatus provide information about the functions of the single components of a mobile telephone, and in particular about the fulfillment of standardized limiting values. Applications thereof are, e.g. in a service depot or for the end control of the manufacturer.

For measuring the transmission quality, preferably a measurement of bit error rates is conducted. To this purpose data transmitted by the tester are sent back again to the tester using the loop back function. The measurement of bit error rates is an excellent tool to determine the sensitivity of the receiver of a mobile or cellular telephone. When measuring the receiver sensitivity at a service depot the tester reduces defined reception levels of the mobile telephone—starting from a reasonable starting value of about −95 dBm in steps until the bit error rate is inadmissibly high. The reception level (in dBm) with which just yet acceptable values are achieved is the sensitivity of the mobile station. When measuring the receiver sensitivity during end control of a manufacturer the fulfillment of the specifications is tested. During those measurements this minimum received power is measured at the antenna coupling device of the mobile telephone at which the bit error rate or frame error rate does not rise above a pre-determined or preset value. A corresponding dynamic range is the input power range of the antenna coupling device of the mobile station in which the bit error rate or frame error rate does not rise above a pre-determined level. During the measurement the number of bits or frames of bits transmitted by the tester and the number of “good” bits received by the mobile station are counted. The goal of the function test of the measurement of the receiver sensitivity is to ensure that the mobile telephone has a sufficient reception range.

In particular, for digital communication systems such as according to the CDMA or cdmaOne standard the testing is more difficult due to error protection mechanisms such as convolutional coding and forward error correction, FEC. This is due to the fact that as a consequence of such protection mechanisms errors do only occur very rarely and always relate to entire data blocks or frames. Therefore, in this case as an error rate always a frame error rate (FER) is used. For a more exact checking whether a mobile telephone has a receiver sensitivity according to the specifications long measurement times are necessary. A typical value for a limiting value or threshold value for the frame error rate is 0.005 which has to be achieved with a safety of 95%. The threshold value of 0.005 corresponds to one error present per 200 frames. Assuming a χ²-distribution (chi-square-distribution) at least 600 blocks have to be transmitted with a maximum number of errors of one in order to achieve the necessary safety of 95%. At a transmission duration of about 20 milliseconds per frame this corresponds to a minimum testing time of 12 seconds. However, the testing time can be much longer up to about 30 to about 50 seconds, if more than one frame error occurs during the measurement. In particular, therefore, a function test of a mobile communication device according to the CDMA, cdmaOne or the like mobile communication standard lasts much longer than the function test of a GSM mobile telephone. In particular the manufacturers of such mobile telephones, therefore, have always to find a comprise between the quality of the components used and the resulting testing time. In other words this means that a less expensive mobile telephone turns in fact out to be more expensive in the function test subsequent to the production. This argument means, expressed differently, that an elaborately manufactured and hence more expensive mobile telephone is cheaper to test.

### OBJECTS OF THE INVENTION

It is, therefore, an object of the present invention to overcome the drawbacks of the prior art and, in particular, to conduct a testing of the receiver sensitivity and a measurement of the bit error rate in a faster manner than known heretobefore.

### SUMMARY OF THE INVENTION

The object according to the invention is solved by a method for measuring the receiver sensitivity of communication terminals provided for operation in a digital communication net, wherein the fulfillment of a first criterion at a pre-determined data transmission rate and at a pre-determined reception level is tested wherein said first criterion in particular corresponds to the specifications for operation in the network characterized in that the testing is conducted at a higher data transmission rate than the pre-determined data transmission rate and at the pre-determined reception level wherein the fulfillment of a second criterion is tested and wherein the second criterion is determined from the first criterion.

Further, this object is solved by a method for measuring the bit error rates of communication terminals provided for operation in a digital communication net wherein at a pre-determined data transmission rate and a pre-determined reception level a first bit error rate has to be obtained which in particular corresponds to the specifications for operation in the network characterized in that the measurement is conducted at a higher data transmission rate than the pre-determined data transmission rate at the pre-determined reception level, wherein at the higher data transmission rate a second bit error rate is obtained, and wherein the first bit error rate is determined from the second bit error rate.

By carrying out the measurement of the frame error rate and the testing of the receiver sensitivity, respectively, at a higher rate of data transmission which, in particular, does not correspond to the rate of data transmission provided for operation the measurement time is significantly reduced.

Preferably, the communication terminals are mobile or cellular telephones, in particular according to the CDMA standard or the cdmaOne standard. When using a code division multiple access method or the like method the measurement of the receiver sensitivity lasts particularly long as was explained above.

Preferably, it is checked whether the first frame error rate is smaller than a pre-determined threshold value at a pre-determined safety of probability. To this purpose the second frame error rate obtained at higher rate of data transmission is compared to a second pre-determined threshold value. The second pre-determined threshold value which is in particular a function of the rate of data transmission and the protection mechanisms resulting therefrom is preferably determined from the first threshold value and the rate of data transmission. This can in particular be realized by using a table of values or look-up table. Preferably, according to the pre-determined safety a number of bits or frames is examined for the presence of an error wherein the measurement is ended when the frame error rate is smaller than the pre-determined threshold value with a pre-determined safety or when the necessary safety can not be achieved anymore within a pre-determinable maximum measurement duration.

Further preferred embodiments of the invention are disclosed in the dependent claims.

### BRIEF DESCRIPTION OF THE DRAWINGS

The invention, as well as further features, advantages, goals and applications thereof will be described in the following taking reference to the accompanying drawings. Therein, all described or illustrated features alone or in any reasonable combination form the subject-matter of the present invention independent of their summary in the claims or the dependencies thereof. In the drawings:

FIG. 1 shows a diagram for illustrating of the method according to the present invention.

### DETAILLED DESCRIPTION OF PREFERRED EMBODIMENTS

According to the preferred embodiment of the present invention the measurement of a bit error rate or, in particular of a frame error rate, is used in order to determine the receiver sensitivity of a mobile communication device, in particular a mobile or cellular telephone. To this purpose the reception level of a mobile telephone is stepwise reduced from a starting value by command signals until the bit error rate is unduly or unacceptably high. The reception level with which just yet acceptable measurement values can be achieved represents the sensitivity of the mobile telephone. As mentioned above a respective frame error rate is determined due to protection mechanisms. Therefore, in more detail with various reception signals it is determined whether the frame error rate fulfills a pre-determined specification. The preferred embodiment relates to testing of a mobile station according to the cdmaOne standard.

When testing the sensitivity the frame error rate is predominantly determined by two criteria. This is on the one hand the signal strength or signal level and on the other hand the protection mechanism used. As an example a signal level of about −104 dBm and a data transmission of about 9,600 bps is used. Using those values the receiver sensitivity of the mobile telephone shall be tested during end control of a manufacturer. The data transmission of 9.600 bps determines the protection mechanism used such as convolutional coding or forward error correction.

Therefore, as an example a specification to be fulfilled requires that the frame error rate is smaller than 0.005 at a signal level of −104 dBm and a data transmission rate of 9,600 bps. As explained above in the introductory portion of the specification this corresponds to a minimum testing time of 12 seconds wherein this testing duration can be much longer depending on the course of the measurement up to a plurality of times of the minimum time. According to the present invention the rate of data transmission is increased, e.g. to a value of 14,400 bps. Inasmuch as the rate of data transmission determines the protection mechanism the threshold value of 0.005 (data transmission rate: 9,600 bps) corresponds now to a threshold value of 0.03 (data transmission rate: 14,400 bps). The calculation of the threshold value is made assuming a Poisson distribution of the errors which corresponds to the assumption that all errors occur independently of each other. This results for the measured frame error rate in an upper limit of

FER_{measured}=2*FER_{specified}*k/χ²(1−C,2k).

In this equation the following abbreviations are used: FER_{measured} the measured error rate, FER_{specified} a specified or pre-determined error rate, C the pre-determined safety that the true error rate is smaller than the specified or pre-determined error FER_{specified} and the k number of the errors occurred. The new threshold value is larger than the old threshold value because there is less protection at an increased transmission rate. Thus, the higher threshold value of 0.03 corresponds one error occurring in 34 frames. Assuming a chi-square-distribution this frame error rate can be guaranteed with a safety of 95% if in 100 frames one or no error occurs. This number is much faster, e.g. in 2 seconds, transmitted because there is a transmission time for one frame of about 20 milliseconds. Hence, the method according to the invention for testing the receiver sensitivity is about six times faster than the conventional method which uses for testing the receiver sensitivity the rate of data transmission used for operation in the communication net. In particular, it has to be noted that by slightly less than a doubling of the data transmission rate a factor of six can be achieved due to the non-linear correlations which result from the error protection mechanisms and the “granularity” relating thereto.

In contrast to the conventional method according to the present invention only the transmission speed, e.g. the rate of data transmission, and thereby the protection mechanism is changed. All other parameters (testing set-up, signal strength . . . ) are not changed so that also the signal-to-noise ratio in the mobile telephone remains unchanged. However, this means that also the transmission errors resulting from this signal-to-noise ratio occur equally frequent and that these errors are more less compensated by the different protection mechanisms. Thereby, it is ensured that the testing criteria according to the present invention and according to the prior art are equivalent, e.g. that a mobile telephone which passes the test at an increased transmission rate using an error rate adapted thereto does also pass the original test with a lower transmission rate and vice versa.

According to the present invention the measurement results which have been obtained at the higher transmission speed are transformed into equivalent values at a lower speed. Preferably, the measurement results are presented to a user on a display device. The testing of the receiver sensitivity is ended when the result is achieved with the necessary safety or when so many errors have occurred that it cannot be achieved anymore with safety.

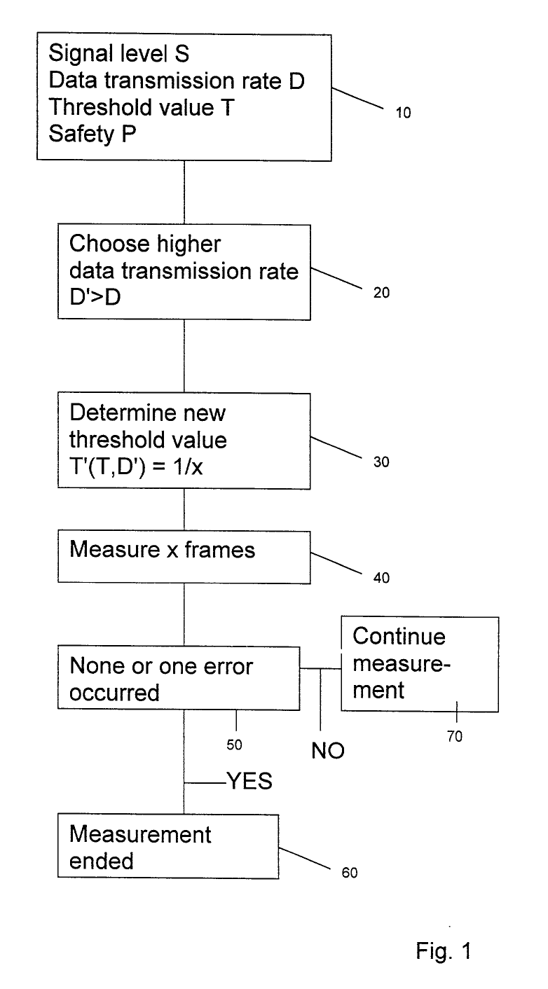

In FIG. 1 the method according to the present invention for determining a frame error rate is schematically illustrated in a more abstract form. In a step 10 the measurement criteria are determined according to a pre-determined mobile communication standard. The corresponding values are preferably adjustable. Most specifically, a signal level S, a data transmission rate D, a threshold value T and a safety or probability P is pre-determined. This means that a pre-determined specification is fulfilled if at a signal level S and a data transmission rate D the bit error rate or frame error rate is below the pre-determined threshold value T with an appropriate safety P. The system now selects a higher data transmission rate D′ which is higher than D. The higher data transmission rate D′ will in particular depend on the total measurement time desired for the measurement as well as from system capacities. The higher data transmission rate is set in step 20. In step 30 a new threshold value T′ resulting therefrom which is higher than T is determined. The threshold value T′ depends on the old threshold value and on the data transmission rate increased in step 20 to D′. It has to be noted that the threshold value T′ can be written as 1/x wherein x represents the number of frames in which one or no error is allowed to occur. In step 40 x frames are awaited and the frames with errors are counted. In step 50 it is determined whether during the measurement of step 40 zero or one error has occurred. If the result of this question is YES then the measurement is ended in step 60 and the test is passed. If the result of step 50 is NO in step 70 further frames are tested with regard to the presence of errors until the point in time when the result has been achieved with the necessary safety or when so many errors have occurred that it can not be achieved with safety in a pre-determinable maximum measurement time. As an alternative to the illustrated method also basically for a pre-determined measurement time the measurement can be conducted wherein the resulting actual error rate is compared to the desired error rate dependent on the safety.

The invention has been described above taking reference to preferred embodiments thereof. However, it is obvious to a skilled person that various variations and modifications can be made without departing from the spirit and scope underlying the invention.

We claim:

1. Method for measuring the receiver sensitivity of communication terminals provided for operation in a digital communication net, wherein the fulfillment of a first criterion at a pre-determined data transmission rate and at a pre-determined reception level is tested characterized in that the testing is conducted at a higher data transmission rate than the pre-determined data transmission rate and at the pre-determined reception level wherein the fulfillment of a second criterion is tested and wherein the second criterion is determined from the first criterion.

2. Method according to claim 1, wherein the criterion is that a bit error rate or frame error rate is smaller than a pre-determined threshold value with a pre-determined safety.

3. Method according to claim 2, wherein the second pre-determined threshold value is a function of the first pre-determined threshold value and the higher data transmission rate.

4. Method according to claim 3, wherein in accordance with the pre-determined safety a number of frames is examined for the presence of an error wherein the measurement is ended when the frame error rate is smaller than the pre-determined threshold value with the pre-determined safety or when the necessary safety cannot be achieved in a pre-determined maximum measurement time.

5. Method for measuring the bit error rates of communication terminals provided for operation in a digital communication net wherein at a pre-determined data transmission rate and a pre-determined reception level a first bit error rate has to be obtained characterized in that the measurement is conducted at a higher data transmission rate than the pre-determined data transmission rate at the pre-determined reception level, wherein at the higher data transmission rate a second bit error rate is obtained, and wherein the first bit error rate is determined from the second bit error rate.

6. Method according to claim 5, wherein the communication terminals are mobile or cellular telephones, in particular according to the CDMA standard.

7. Method according to claim 6, wherein the bit error rate is a frame error rate.

8. Method according to claim 7, wherein it is further checked whether the first bit error rate is smaller than a pre-determined threshold value with a pre-determined safety.

9. Method according to claim 8, wherein for checking whether the first bit error rate is smaller than the pre-determined threshold value with a pre-determined safety the second bit error rate is compared to a pre-determined threshold value.

10. Method according to claim 9, wherein the threshold value is a function of the data transmission rate.

11. Method according to claim 10, wherein the second threshold value is determined from the first threshold value.

12. Method according to claim 11, wherein in accordance with the pre-determined safety a number of frames is examined for the presence of an error wherein the measurement is ended when the frame error rate is smaller than the pre-determined threshold value with a pre-determined safety or when the necessary safety can not be achieved anymore within a pre-determined maximum measurement time.

13. Testing device for measuring the receiver sensitivity of communication terminals provided for operation in a digital communication net, wherein the fulfillment of a first criterion at a pre-determined data transmission rate and at a pre-determined reception level is tested characterized in that the testing is conducted at a higher data transmission rate than the pre-determined data transmission rate and at the pre-determined reception level wherein the fulfillment of a second criterion is tested and wherein the second criterion is determined from the first criterion.

14. Testing device for measuring the bit error rates of communication terminals provided for operation in a digital communication net wherein at a pre-determined data transmission rate and a pre-determined reception level a first bit error rate has to be obtained characterized in that the measurement is conducted at a higher data transmission rate than the pre-determined data transmission rate at the pre-determined reception level, wherein at the higher data transmission rate a second bit error rate is obtained, and wherein the first bit error rate is determined from the second bit error rate.

15. Testing apparatus according to claim 14, wherein the testing apparatus comprises a control means for controlling the process of testing.

16. Testing apparatus according to claim 15, wherein the testing apparatus comprises a display means for displaying a measurement or test result.
